(19) United States
(12) Patent Application Publication
(10) Pub. No.: US 2008/0028282 A1
(43) Pub. Date: Jan. 31, 2008

(54) RECEIVER ARCHITECTURE HAVING A LDPC DECODER WITH AN IMPROVED LLR UPDATE METHOD FOR MEMORY REDUCTION

(75) Inventors: Yan Zhong, San Jose, CA (US); Abhiram Prabhakar, Pleasanton, CA (US); Dinesh Venkatachalam, Fermont, CA (US)

Correspondence Address: FRANK F. TIAN, 331-4A THIRD AVENUE, LONG BEACH, NJ, 07740, US

(73) Assignee: LEGEND SILICON, FREMONT, CA (US)

(21) Appl. No.: 11/557,491

(22) Filed: Nov. 7, 2006

Related U.S. Application Data
(63) Continuation of application No. 60/820,319, filed on Jul. 25, 2006.
Application No. 60/820,319 is a continuation of application No. 60/820,313, filed on Jul. 25, 2006.

(51) Int. Cl. H03M 13/03

(52) U.S. Cl. 714/794

(57) ABSTRACT

The present invention provides a reduced memory implementation for the min-sum algorithm compared to traditional hardware implementations. The improvement includes innovative MIN_SUM method with reduced memory requirements suitable of computer implementation that combines the traditional row update process and column update process into a single process, in that the traditional CNU unit and VNU unit are combined into a single CVNU unit. The improvement not only reduces the time required for decoding by half, but also reduces the logic and routing efforts. Furthermore, instead of storing the whole intermediate LLR values using a significant number of memories, only a set of parameters associated with the intermediate LLR values is stored. The set of parameters includes: 1. sign of LLR; 2. the minimum LLR, 3. sub-minimum LLR, and 4. the column location of minimum value in each row. Therefore, as compared with the traditional LDPC decoder implementation, the required memory size of the present invention is significantly or tremendously reduced.

### REFERENCE TO RELATED APPLICATIONS

This application claims an invention which was disclosed in Provisional Applications Nos. 60/820,319, filed Jul. 25, 2006 entitled “Receiver For An LDPC based TDS-OFDM Communication System”; and 60/820,313, filed Jul. 25, 2006 entitled “LDPC Code of Various Rates for a[n] LDPC BASED TDS-OFDM Communication System and Code Generation Method thereof”. The benefit under 35 USC §119(e) of the United States provisional application is hereby claimed, and the aforementioned applications are hereby incorporated herein by reference.

### FIELD OF THE INVENTION

The present invention relates generally to communication devices. More specifically, the present invention relates to a receiver having a LDPC decoder using an improved LLR update method with reduced memory requirements.

### BACKGROUND

OFDM (Orthogonal frequency-division multiplexing) is known. U.S. Pat. No. 3,488,445 to Chang describes an apparatus and method for frequency multiplexing of a plurality of data signals simultaneously on a plurality of mutually orthogonal carrier waves such that overlapping, but band-limited, frequency spectra are produced without causing interchannel and intersymbol interferences. Amplitude and phase characteristics of narrow-band filters are specified for each channel in terms of their symmetries alone. The same signal protection against channel noise is provided as though the signals in each channel were transmitted through an independent medium and intersymbol interference were eliminated by reducing the data rate. As the number of channels is increased, the overall data rate approaches the theoretical maximum.

OFDM transreceivers are known. U.S. Pat. No. 5,282,222 to Fattouche et al describes a method for allowing a number of wireless transceivers to exchange information (data, voice or video) with each other. A first frame of information is multiplexed over a number of wideband frequency bands at a first transceiver, and the information transmitted to a second transceiver. The information is received and processed at the second transceiver. The information is differentially encoded using phase shift keying. In addition, after a pre-selected time interval, the first transceiver may transmit again. During the preselected time interval, the second transceiver may exchange information with another transceiver in a time duplex fashion. The processing of the signal at the second transceiver may include estimating the phase differential of the transmitted signal and pre-distorting the transmitted signal. A transceiver includes an encoder for encoding information, a wideband frequency division multiplexer for multiplexing the information onto wideband frequency voice channels, and a local oscillator for upconverting the multiplexed information. The apparatus may include a processor for applying a Fourier transform to the multiplexed information to bring the information into the time domain for transmission.

Using PN (pseudo-noise) as the guard interval in an OFDM is known. U.S. Pat. No. 7,072,289 to Yang et al describes a method of estimating timing of at least one of the beginning and the end of a transmitted signal segment in the presence of time delay in a signal transmission channel. Each of a sequence of signal frames is provided with a pseudo-noise (PN) m-sequences, where the PN sequences satisfy selected orthogonality and closures relations. A convolution signal is formed between a received signal and the sequence of PN segments and is subtracted from the received signal to identify the beginning and/or end of a PN segment within the received signal. PN sequences are used for timing recovery, for carrier frequency recovery, for estimation of transmission channel characteristics, for synchronization of received signal frames, and as a replacement for guard intervals in an OFDM context.

During information transmission, especially in a receiver, a LLR (log-likelihood-ratio) of a set of symbols needs to be determined. Traditionally, a MIN-SUM method suitable of computer implementation such as hardware implementation is performed. The traditional MIN-SUM method suitable of computer implementation, such as hardware implementation, typically requires separate CNU unit and VNU units for computational purposes. Also separate row update process and column update process are required. Further, the whole intermediate LLR values correspond to each non-zero element of a parity check H-Matrix need to be stored, thereby require the use significant numbers of memories.

Forward error correction (FEC) is known to be used to correct errors at the receiver end. Low-Density Parity-Check (LDPC) codes are a class of FEC codes. The traditional Two-Phase Message Passing (TPMP) scheduling used for LDPC decoding typically requires a separate column update process and is followed by the row update process for each and every iteration. Another approach known as a Layered/Turbo scheduling approach typical interlaces the row update process with column update process that increases the convergence speed of the decoding algorithm thereby decreasing the decoding time. The traditional LDPC decoder typically requires storing intermediate LLR information for each non zero element in the parity check matrix which requires significant amount of memory. It is noted that scheduling refers to the sequence of operations performed at the decoder. There are several algorithms used for decoding LDPC codes such as Sum-Product Algorithm (SPA), Min-Sum Algorithm (MS) etc. What has been implemented before is LDPC decoder with Layered/Turbo Scheduling implementing SPA algorithm. This increases convergence speed and decreases decoding time. Also Min-Sum algorithm has been implemented without any memory reduction compared to SPA algorithm. As can be seen, there is a need for reducing these memories. Therefore, there is a need for improved method with reduced memory requirements for the LLR computation

### SUMMARY OF THE INVENTION

An improvement over the traditional MIN_SUM method with reduced memory requirements suitable of computer implementation including hardware implementation that combines the traditional row update process and column update process into a single process is provided.

A Min-Sum decoder architecture with reduced memory requirements & faster decoding together and not separately is provided.

An improvement over the traditional MIN_SUM method with reduced memory requirements that reduces the time required for decoding in about half, and substantially reduces the logic and routing efforts is provided. By not storing the whole intermediate LLR values correspond to each non-zero element of a parity check H-Matrix, thereby using a significant number of memories, only a significantly reduced set of parameters associated with the intermediate LLR values is stored. Therefore, as compared with the traditional LDPC decoder implementation, the required memory size of the present invention is significantly reduced.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a receiver in accordance with some embodiments of the invention.

FIG. 2 is an example of a coding-decoding communication system.

FIG. 3 is an example of a controller of the present invention.

FIG. 4 is an example of a block diagram of the present invention.

FIG. 5 is an exemplified flowchart of the present invention.

FIG. 6 is an exemplified parity matrix associated with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to improvement over the traditional MIN_SUM method that reduces the memory requirement, and reduces the time required for decoding in about half, and reduces the logic and routing efforts is provided. By not storing the whole intermediate LLR values corresponding to each non-zero element of a parity check H-Matrix using a significant number of memories, only a small set of parameters associated with the intermediate LLR values is stored in the present invention. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of relating to improvement over the traditional MIN_SUM method that reduces the memory requirement, and reduces the time required for decoding in about half, as well as reduces the logic and routing efforts is provided. In the exemplified embodiments, It is noted that the processors include Finite State Machines, which are used in the preferred embodiment. Instead of storing the whole intermediate LLR values correspond to each non-zero element of the H-Matrix, thereby using a significant number of memories, only a limited set of parameters associated with the intermediate LLR values is stored herein this preferred embodiment. The non-processor circuits may include, but are not limited to, a radio receiver, a radio transmitter, signal drivers, clock circuits, power source circuits, and user input devices. As such, these functions may be interpreted as steps of a method with reduced memory requirements to perform an improved MIN_SUM method that reduces the time required for decoding in about half, and reduces the logic and routing efforts is provided. By using the invention, for the ASIC implementation of a LDPC decoder, not only the required chip area is significantly reduced, but also the processing time is reduced by about half, as a result, the power dissipation is much lowered. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The present invention comprises a Layered Min-Sum LDPC decoder architecture with reduced memory requirements. In the decoder, it is observed that the magnitude of intermediate LLR values for a row can take only two different values after a row update and they are all different after a column update. Instead of storing all the different magnitudes for LLR, values in each row are stored in the present invention having fewer set of parameters for a row from which the different LLR values after a row or column update can be derived. Therefore, as compared to the traditional LDPC decoder implementation, the required memory size of the present invention is significantly reduced.

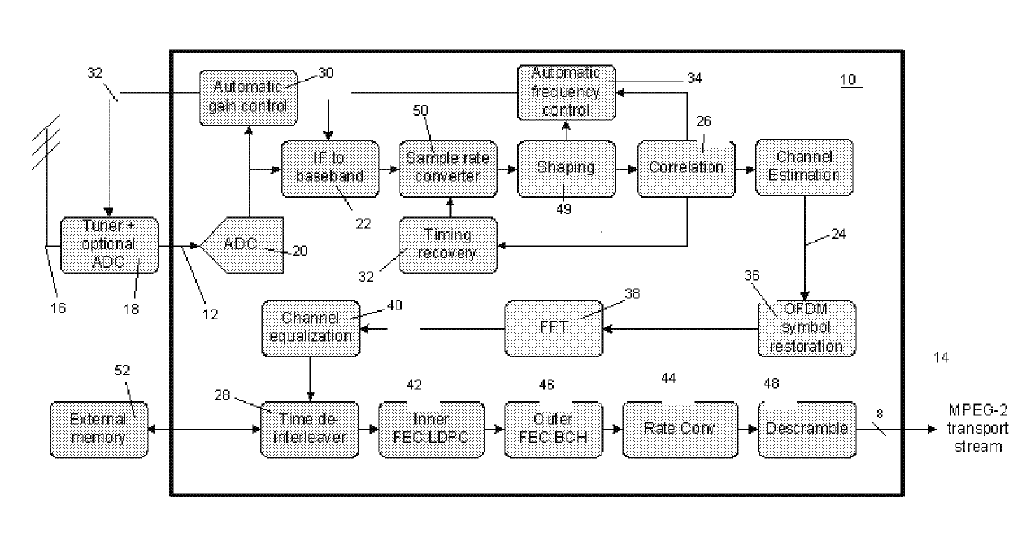

Referring to FIG. 1, a receiver 10 for implementing a LDPC based TDS-OFDM communication system is shown. In other words, FIG. 1 is a block diagram illustrating the functional blocks of an LDPC based TDS-OFDM receiver 10. Demodulation herein follows the principles of a TDS-OFDM modulation scheme. Error correction mechanism is based on LDPC. The primary objectives of the receiver 10 is to determine from a noise-perturbed system, which of the finite set of waveforms have been sent by a transmitter and using an assortment of signal processing techniques to reproduce a finite set of discrete messages sent by the transmitter

The block diagram of FIG. 1 illustrates the signals and key processing steps of the receiver 10. It is assumed that input signal 12 to the receiver 10 is a down-converted digital signal. The output signal 14 of receiver 10 is a MPEG-2 transport stream. More specifically, the RF (radio frequency) input signals 16 are received by an RF tuner 18, where the RF input signals are converted to low-IF (intermediate frequency) or zero-IF signals 12. The low-IF or zero-IF signals 12 are provided to the receiver 10 as analog signals or as digital signals (through an optional analog-to-digital converter 20).

In the receiver 10, the IF signals are converted to base-band signals 22. TDS-OFDM (Time domain synchronous-Orthogonal frequency-division multiplexing) demodulation is then performed according to the parameters of the LDPC (low-density parity-check) based upon the TDS-OFDM modulation scheme. The output of the channel estimation 24 and correlation block 26 is sent to a time de-interleaver 28 and then to the forward error correction block. The output signal 14 of the receiver 10 is a parallel or serial MPEG-2 transport stream including valid data, synchronization, and clock signals. The configuration parameters of the receiver 10 can be detected or automatically programmed, or manually set. The main configurable parameters for the receiver 10 include: (1) Sub carrier modulation type: QPSK, 16 QAM, 64 QAM; (2) FEC rate: 0.4, 0.6 and 0.8; (3) Guard interval: 420 or 945 symbols; (4) Time de-interleaver mode: 0, 240 or 720 symbols; (5) Control frames detection; and (6) Channel bandwidth: 6, 7, or 8 MHz.

The functional blocks of the receiver 10 are described as follows.

Automatic gain control (AGC) block 30 compares the input digitized signal strength with a reference. The difference is filtered and the filter value 32 is used to control the gain of the amplifier 18. The analog signal provided by the tuner 12 is sampled by an ADC 20. The resulting signal is centered at a lower IF. For example, sampling a 36 MHz IF signal at 30.4 MHz results in the signal centered at 5.6 MHz. The IF to Baseband block 22 converts the lower IF signal to a complex signal in the baseband. The ADC 20 uses a fixed sampling rate. Conversion from this fixed sampling rate to the OFDM sample rate is achieved using the interpolator in block 22. The timing recovery block 32 computes the timing error and filters the error to drive a Numerically Controlled Oscillator (not shown) that controls the sample timing correction applied in the interpolator of the sample rate converter.

There can be frequency offsets in the input signal 12. The automatic frequency control block 34 calculates the offsets and adjusts the IF to baseband reference IF frequency. To improve capture range and tracking performance, frequency control is done in two stages: coarse and fine. Since the transmitted signal is square root raised cosine filtered, the received signal will be applied with the same function. It is known that signals in a TDS-OFDM system include a PN sequence preceding the IDFT symbol. By correlating the locally generated PN with the incoming signal, it is easy to find the correlation peak (so the frame start can be determined) and other synchronization information such as frequency offset and timing error. Channel time domain response is based on the signal correlation previously obtained. Frequency response is taking the FFT of the time domain response.

In TDS-OFDM, a PN sequence replaces the traditional cyclic prefix. It is thus necessary to remove the PN sequence and restore the channel spreaded OFDM symbol. Block 36 reconstructs the conventional OFDM symbol that can be one-tap equalized. The FFT block 38 performs a FFT such as a 3780 point FFT. Channel equalization 40 is carried out to the FFT 38 transformed data based on the frequency response of the channel. De-rotated data and the channel state information are sent to FEC for further processing.

In the TDS-OFDM receiver 10, the time-deinterleaver 28 is used to increase the resilience to spurious noise. The time-deinterleaver 28 is a convolutional de-interleaver which needs a memory with size B*(B−1)*M/2, where B is the number of the branch, and M is the depth. For the TDS-OFDM receiver 10 of the present embodiment, there are two modes of time de-interleavering. For mode 1, B=52, M=240, and for mode 2, B=52, M=720.

The LDPC decoder 42 is a soft-decision iterative decoder for decoding, for example, a Quasi-Cyclic Low Density Parity Check (QC-LDPC) code provided by a transmitter (not shown). The LDPC decoder 42 is configured to decode at 3 different rates (i.e. rate 0.4, rate 0.6 and rate 0.8) of QC_LDPC codes by sharing the same piece of hardware. The iteration process is either stopped when it reaches the specified maximum iteration number (full iteration), or when the detected error is free during error detecting and correcting process (partial iteration).

The TDS-OFDM modulation/demodulation system is a multi-rate system based on multiple modulation schemes (QPSK, 16 QAM, 64 QAM), and multiple coding rates (0.4, 0.6, and 0.8), where QPSK stands for Quad Phase Shift Keying and QAM stands for Quadrature Amplitude Modulation. The output of BCH decoder is bit by bit. According to different modulation scheme and coding rates, the rate conversion block combines the bit output of BCH decoder to bytes, and adjusts the speed of byte output clock to make the receiver 10's MPEG packets outputs evenly distributed during the whole demodulation/decoding process.

The BCH decoder 46 is designed to decode BCH (762, 752) code, which is the shortened binary BCH code of BCH (1023, 1013). The generator polynomial is x̂10+x̂3+1.

Since the data in the transmitter has been randomized using a pseudo-random (PN) sequence before BCH encoder (not shown), the error corrected data by the LDPC/BCH decoder 46 must be de-randomized. The PN sequence may be generated by the polynomial 1+x¹⁴+x¹⁵, with initial condition of 100101010000000. The de-scrambler/de-randomizer 48 will be reset to the initial condition for every signal frame. Otherwise, de-scrambler/de-randomizer 48 will be free running until reset again. The least significant 8-bit will be XORed with the input byte stream.

The data flow through the various blocks of the modulator is as follows. The received RF information 16 is processed by a digital terrestrial tuner 18, which picks the frequency bandwidth of choice to be demodulated and then downconverts the signal 16 to a baseband or low-intermediate frequency. This downconverted information 12 is then converted to the Digital domain through an analog-to-digital data converter 20.

The baseband signal after processing by a sample rate converter 50 is converted to symbols. The PN information found in the guard interval is extracted and correlated with a local PN generator to find the time domain impulse response. The FFT of the time domain impulse response gives the estimated channel response. The correlation 26 is also used for the timing recovery 32 and the frequency estimation and correction of the received signal. The OFDM symbol information in the received data is extracted and passed through a 3780 FFT 38 to obtain the symbol information back in the frequency domain. Using the estimated channel estimation previously obtained, the OFDM symbol is equalized and passed to the FEC decoder.

At the FEC decoder, the time-deinterleaver block 28 performs a deconvolution of the transmitted symbol sequence and passes the 3780 blocks to the inner LDPC decoder 42. The LDPC decoder 42 and BCH decoders 46 which run in a serial manner take in exactly 3780 symbols, remove the 36 TPS symbols and process the remaining 3744 symbols and recover the transmitted transport stream information. The rate conversion 44 adjusts the output data rate and the de-randomizer 48 reconstructs the transmitted stream information. An external memory 52 coupled to the receiver 10 provides memory thereto on a predetermined or as needed basis.

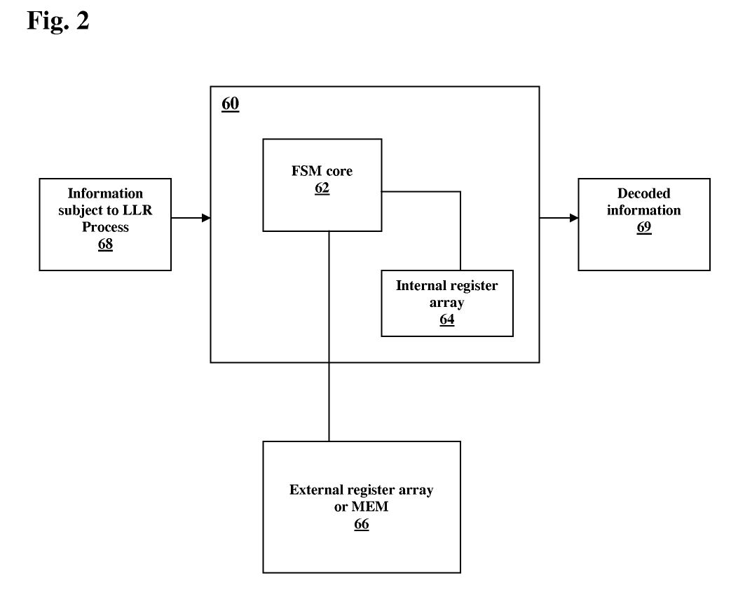

Referring to FIG. 2, a coding-decoding, simplified communication system 60 is shown. Data 62 subject to transmission is encoded by a LDPC (Low Density parity check) encoder 64 at the transmitting end, or transmitter. The output of encoder 64 is modulated by modulator 66 and transmitted via a media or a transmission channel 68. At the receiver end, a de-modulator 70 de-modulates the transmitted information. The de-modulated information is subjected to a LLR (log-likelihood-ratio) process 72, wherein a probability measure is computed and assigned to each bit or symbol of transmitted information from the received channel symbol. The processed information is, in turn, decoded by a LDPC (Low Density parity check) decoder 74 into recovered transmitted data 76.

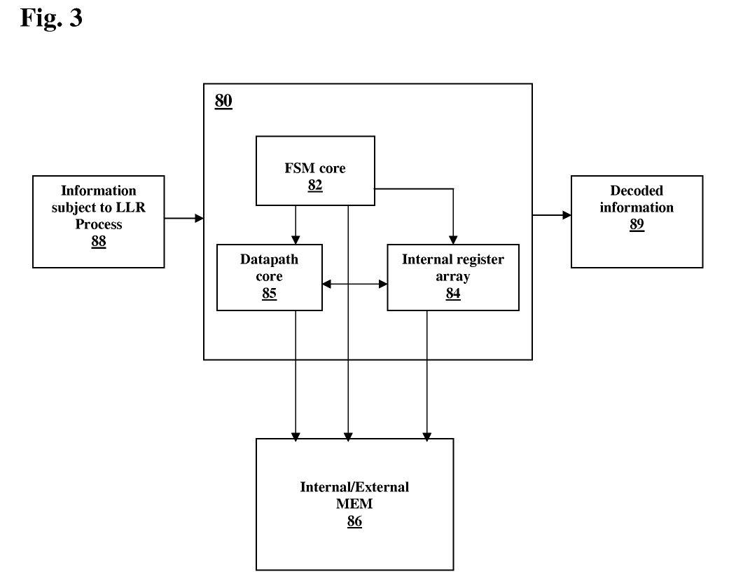

Referring to FIG. 3, a typical LLR (log-likelihood-ratio) processing device is shown. A FSM 80 (finite state machine) having a FSM core 82, an internal register array 84, and a Datapath core 85 is provided. FSM 80 may also be coupled to an internal/external memory 86. FSM is used for such things as correcting inaccuracies associated the data transmission including wireless transmission. A receiver receiving encoded information wirelessly transmitted often needs to perform a determination process to determine the probability or the confidence level of a received bit. In the present context, this probability or the confidence level is the LLR process performed by module 88. The outputs of block 88 are the bits probabilities subject to the LDPC decoding process of FSM 80. In turn, the decoded information 89 are the outputs of FSM 80.

More specifically, FSM 82 may be built using a programmable logic device, a programmable logic controller, logic gates and flip flops or relays. It is used to schedule and control the whole decoding dataflow, the Datapath core 85 mainly consists of a set of mathematical elements, like adders, subtractors, comparators etc., to repeatedly perform the task of correcting inaccuracies associated the data transmission including wireless transmission. The memory 86 is used to store the intermediate parameters associated with the decoding process. At the same time, a hardware implementation requires a register such as internal register array 84 to store state variables, a block of combinational logic which determines the state transition, and a second block of combinational logic that determines the output of a FSM. As can be seen, for operations with large numbers of intermediate parameters, state variables, a significant amount of memory is required that necessarily requires memory space. Furthermore, FSM processing or operation necessarily take time, therefore the more operations there are, the more time is consumed. More time consumption and memory space are both undesirable outcomes in the context of the present invention.

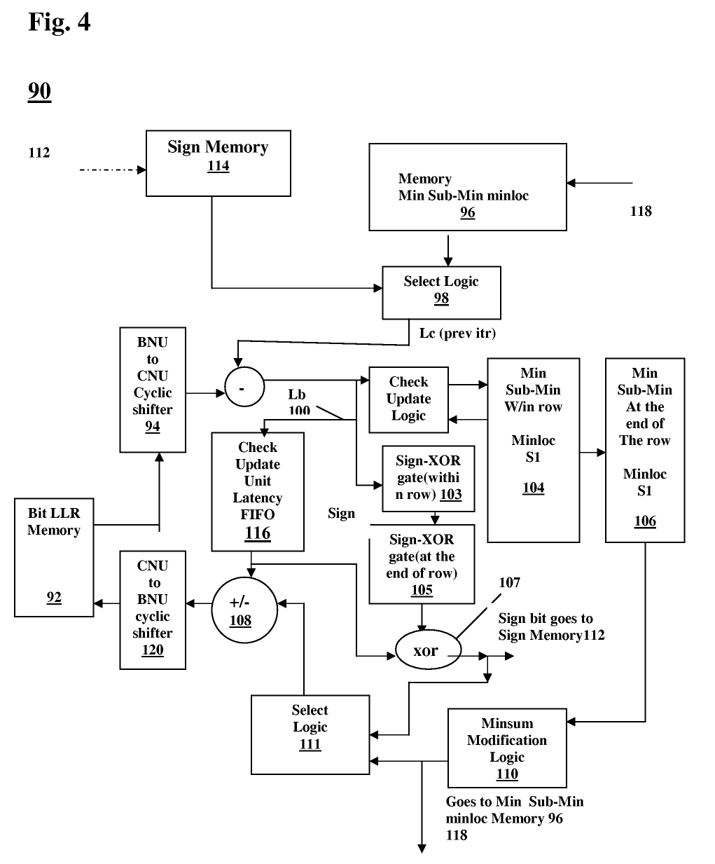

Referring to FIG. 4, function blocks of the improved MIN-SUM method with reduced memory requirements is shown. Min-Sum is a known algorithm. The present invention is not merely improving the Min-Sum algorithm, but also is an implementation of the Min-Sum algorithm that has reduced memory requirements such as less memory or registers are needed or required. Bit LLR memory corresponding to a single row is stored in memory 92. Note that instead of storing values correspond to non-zero elements of a parity check H-Matrix in all of the rows, merely storing information relating to a set of parameters is sufficient for the practice of the present invention. For each cycle, one set of information contained in one element within the row is called out from memory 92 and subjected to a BNU to CNU cyclic shifting by shifter 94. The shifted information is subtracted by a set of MIN or SUB-MIN logic values stored in check value memory (MIN, SUB-MIN, MIN LOC memory 96 and Sign Memory 114), and selected by select logic 98. The differences 100 (L_{b}) is subjected to an update check to see if the value is smaller or bigger than an existing value within the current row by check update logic 102 (CVNU unit). The sign of each L_{b} difference 100 within the current row will be XORed together by sign-xor logic 103. Both the update check and sign-xor are performed until the end of the row. At this juncture, the total sign-xor value, the new MIN and SUB-MIN, and the location of MIN of the current row are known in block 106 or 105. The known MIN and SUB-MIN values are in turn subjected to a min-sum modification logic 110 and are written back to MIN, SUB-MIN, MIN LOC memory 96, as well as input to a select logic 111. Note that if the value is MIN, then select SUB-MIN, otherwise select MIN. Details of the modification logic 110 are disclosed in the commonly assigned U.S. patent application Ser. No. 11/550,394 to Haiyun Yang. The aforementioned application is hereby incorporated herein by reference.

The output sign-xor value of 105 is xored with the sign of output of Check Update Unit Latency FIFO 116, the resultant value 112 of logic XOR 107 is fed to sign memory 114. The resultant value of 111 is further added with a value coming out of Check Update Unit Latency FIFO 116 at adder/subtractor 108. The resultant value 112 of XOR logic 107 is also used as input here to select either addition or subtraction operation as the case maybe. The result of adder/subtractor 108 in turn is subjected to CNU to BNU cyclic shifter 120 to revert back to the original order of the memory 92.

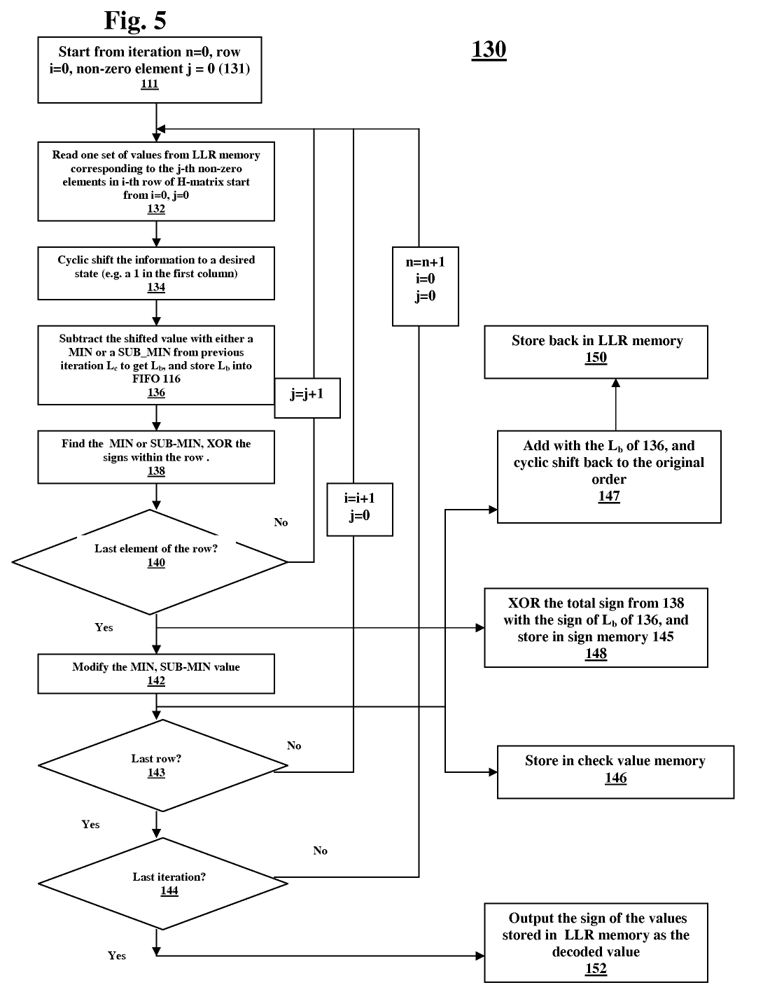

FIG. 5 is an exemplified flowchart 130 of the present invention. Flowchart 130 start from iteration at n=0, with row i=0, and non-zero element j=0 where j denotes a column (Step 131). Read one set of values from the LLR memory corresponding to the j-th non-zero elements in i-th row of a parity check matrix H-matrix starting from i=0, j=0 (Step 132). Perform a cyclic shift which shifts the information to a desired state such as a 1 in the first column (Step 134). Subtract the shifted value with either a MIN or a SUB_MIN from previous iteration L_{c} to get L_{b}, and store L_{b} into FIFO 116 (Step 136). Find the MIN or SUB-MIN, and XOR the signs within the row (Step 138). A determination is made herein as to whether the subject element is the Last element of the row (Step 140).

If the subject element is not the last element of the row, counter j is incremented by one and the process reverts back to Step 132. On the other hand, if the subject element is the last element of the row, the total sign from step 138 is exclusively XORed (XOR) with the sign of L_{b} from the step of 136, are stored in a sign memory (Step 148). Simultaneously, the MIN, SUB-MIN and MIN-LOC values are stored in a check value memory after a Modification step 142 (Step 146), and the value of Lb of step 136 is added/subtracted thereon with a cyclic shift performed therefore shifting back to the original order (Step 147). The shifted result is stored back in the LLR memory (Step 150). At this juncture, a second determination is performed as to whether the row under processing is the last row (Step 143). If negative, counter j is set to zero and counter i to i+1, and the process reverts back to Step 132. If positive, a third determination is performed to determine whether the current iteration is the last iteration (Step 144). If negative, counter j is set to zero and counter i is also set to 0, and counter n is set to n+1 with the process reverting back to Step 132. If positive, the sign of the values stored in a LLR memory is output as the decoded value (Step 152).

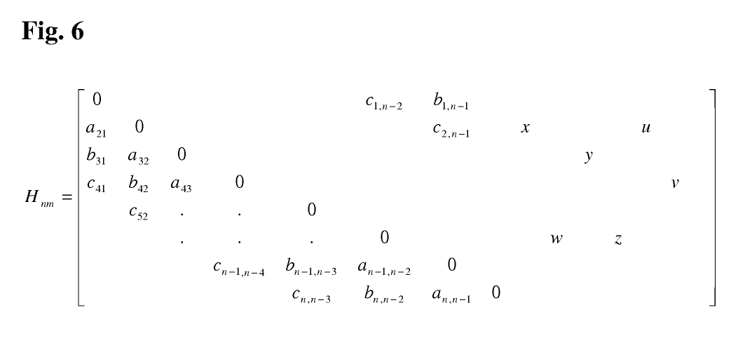

Referring to FIG. 6, an exemplified parity-check matrix H is shown. The matrix has n rows and m columns, with both n, m being positive integers and m>n. Furthermore, resultant parity-check matrix H can be considered as a combination of a square matrix H_{sq} and a remainder Hᵣ. In other words, resultant parity-check matrix H=[H_{sq} Hᵣ]. That is a square matrix and a remainder matrix with the remainder matrix Hᵣ of higher degree than the square matrix H_{sq}. In H_{sq} on the diagonal line are all zero matrices. On the first sub-diagonal line, a series of identical cyclic permutation submatrices is provided. Similarly, on the second sub-diagonal line, a series of identical cyclic permutation submatrices is provided except different the positions for 1s are different from the first sub-diagonal line. On the third sub-diagonal line, a series of identical cyclic permutation submatrices is provided except having different positions for 1s that are different from the first and second sub-diagonal lines. For example, in FIG. 6, for the first subdiagonal in the first row the position of the single 1 is in column 1 (note that the column numbers start from 0 to n−1). Similarly, in the second and third subdiagonals, in the first row the position of the single 1 is in columns 32 and 104 respectively. In other words, the masking matrix Z to a specific code has 1s on a series of three continuous sub-diagonals similar the sub-diagonals of H, i.e. aᵢⱼ, bᵢⱼ, and cᵢⱼ. Details of forming the parity check matrix is disclosed in the commonly assigned U.S. patent application Ser. No. 11/550,567 to Lei Chen. The aforementioned application is hereby incorporated herein by reference.

In a decoder that has an improved LLR (log-likelihood-ratio) update method is provided. The method comprising the steps of: providing a parity check matrix; and using merely a set of parameters on a row of the parity check matrix instead of data of the whole non-zero elements of the parity check matrix; thereby saving memory space and process time.

A receiver including a decoder is provided. The decoder has an improved LLR (log-likelihood-ratio) update method, said method comprising the steps of: providing a parity check matrix; and using merely a set of parameters on a row of the parity check matrix instead of data of the whole non-zero elements of the parity check matrix; thereby saving memory space and process time.

The present invention provides a reduced memory implementation for the min-sum algorithm compared to traditional hardware implementations. The improvement includes innovative MIN_SUM method with reduced memory requirements suitable of both computer implementation and hardware implementation that combines the traditional row update process and column update process into a single process, in that the traditional CNU unit and VNU unit are combined into a single CVNU unit. The improvement not only reduces the time required for decoding by half, but also reduces the logic and routing efforts. Furthermore, instead of storing the whole intermediate LLR values using a significant number of memories, only a set of parameters associated with the intermediate LLR values is stored. The set of parameters includes: 1. sign of LLR; 2. the minimum LLR, 3. sub-minimum LLR, and 4. the column location of minimum value in each row. Therefore, as compared with the traditional LDPC decoder implementation, the required memory size of the present invention is significantly or tremendously reduced.

It is noted that the present invention contemplates using the PN sequence disclosed in U.S. Pat. No. 7,072,289 to Yang et al which is hereby incorporated herein by reference.

It is further noted that a computer implementation typically works on the software algorithm, which is not related to the method of the present invention. By computer implementation, it is meant that hardware implementation is contemplated. There are two methods of implementation TPMP or layered decoding. What the present invention has implemented herein is Layered decoding with reduced memory requirements for storing intermediate LLR values.

It is still further noted that the algorithm of the present invention is not any instruction set that is processed by a computer (CPU). By algorithm we mean a procedure that is implemented using a set of dedicated hardware. The algorithm focuses on the hardware architecture.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. In a decoder having an improved LLR (log-likelihood-ratio) update method, said method comprising the steps of:
providing a parity check matrix; and
using merely a set of parameters on a row of the parity check matrix instead of data of the whole non-zero elements of the parity check matrix; thereby saving memory space and process time.

2. The method of claim 1, wherein the set of parameters comprises a sign of LLR; a minimum LLR for the row, sub-minimum LLR for the row, and a column location of the minimum value in each row.

3. The method of claim 1, wherein only the set of parameters need to be stored or processed.

4. The method of claim 1, wherein the parity check matrix comprised a multiplicity of zeros therein.

5. The method of claim 1, wherein memory requirements is reduced.

6. A receiver comprising:
a decoder having an improved LLR (log-likelihood-ratio) update method, said method comprising the steps of:
providing a parity check matrix; and
using merely a set of parameters on a row of the parity check matrix instead of data of the whole non-zero elements of the parity check matrix; thereby saving memory space and process time.

7. The method of claim 6, wherein the set of parameters comprises a sign of LLR; a minimum LLR for the row, sub-minimum LLR for the row, and a column location of the minimum value in each row.

8. The method of claim 6, wherein only the set of parameters need to be stored.

9. The method of claim 6, wherein the parity check matrix comprised a multiplicity of zeros therein.

10. The method of claim 6, wherein memory requirements is reduced.
